(19) United States
(12) Patent Application Publication
(10) Pub. No.: US 2023/0093862 A1
(43) Pub. Date: Mar. 30, 2023

(54) LASER BLAST SHIELD

(71) Applicant: WKW North America Holding, Inc., Troy, MI (US)

(72) Inventor: James P. Opdycke, Portage, MI (US)

(73) Assignee: WKW North America Holding, Inc., Troy, MI (US)

(21) Appl. No.: 17/486,050

(22) Filed: Sep. 27, 2021

(51) Int. Cl. B23K 26/18; B23K 26/50; H01L 21/268

(52) U.S. Cl. CPC B23K 26/18; B23K 26/50; H01L 21/268; B23K 2103/10

(57) ABSTRACT

A laser blast shield for preventing damage to a first wall of a workpiece opposite a second wall being cut by a laser includes a metal substrate having a micro-textured topology and a highly reflective and thermally conductive metal coating deposited over the micro-textured surface to facilitate spreading of residual laser energy penetrating the second surface and absorption of the laser energy throughout the body of the blast shield.

### FIELD OF THE DISCLOSURE

This disclosure relates to the field of technology associated with laser cutting through metal workpieces and more particular to a laser blast shield and a method of using the same to shield a first wall portion of a workpiece against damage during high speed laser cutting through a second wall portion of the metal tubular structure opposite the first wall portion.

### BACKGROUND OF THE DISCLOSURE

A conventional step in the manufacturing of a vehicle running board having a tubular metal body and rubber or plastic anti-slip step pads and end caps attached to an upper (Class A) surface and ends of the tubular metal body involves cutting attachment holes or apertures into the surface of the tubular metal body. The anti-slip step pads and end caps can include integrally formed pegs that are frictionally fitted into the holes or into anchor sleeves mounted in the holes to securely attach the anti-slip pads to the tubular metal body. It is particularly advantageous to use laser cutting techniques for creating the attachment apertures. Such techniques are amenable to full automation and high-speed production. However, a problem arises from the difficulty of concurrently managing the power to the laser cutter to achieve high-speed cutting without damaging a wall portion of the tubular metal body opposite of a portion through which the apertures are being cut. Specifically, a lower power level that allows cutting of apertures without cutting through or marring a portion of the tubular body opposite the portion being cut has a longer cycle time that results in lower production rates and high manufacturing costs. Higher power levels that facilitate high-speed production can cause marring or undesirable cutting that promotes corrosion, and which can result in undesirable rates of rejected parts.

### SUMMARY OF THE DISCLOSURE

Described are a laser cutting tool blast shield and method of using the same to facilitate high-speed cutting operations on a tubular metal workpiece without damaging a portion of the workpiece opposite the portion being cut.

The blast shield can include a surface having a micro-textured topology that scatters impinging laser energy along the surface of the blast shield.

The blast shield can include a highly thermally conductive coating. A preferred thermally conductive coating is gold or silver. The thermally conductive coating may be applied to an untreated surface or a micro-textured surface.

The body of the blast shield, which may be micro-textured and/or provided with a thermally conductive coating, can be comprised of a metal having a relatively high thermal conductivity and a relatively low cost, with an aluminum body being preferred.

### BRIEF DESCRIPTION OF THE DRAWINGS

FIG. 1 is a perspective view showing a tubular workpiece (extruded aluminum running board, such as for, but not limited to, light duty pickup trucks) defining a hollow interior into which a laser blast shield has been inserted to allow high-speed laser cutting of apertures on a top side of the workpiece while the bottom side of the workpiece is shielded from damage from the laser cutter.

FIG. 2 is a transverse, cross-sectional view of the workpiece shown in FIG. 1 with the blast shield inserted into the hollow space.

FIG. 3 is an enlarged cross-sectional view of the blast shield showing surface detail.

FIG. 4 is a perspective view of an alternative embodiment using a more complex workpiece defining two adjacent tubular structures, each containing a separate blast shield to facilitate laser cutting on one side (e.g., top or bottom) of the tubular structure, while an opposite side of the tubular structure is protected against damage from the laser cutter.

FIG. 5 is a transverse cross-sectional view of the workpiece shown in FIG. 4 with the two blast shields inserted into the respective adjacent tubular structures.

### DETAILED DESCRIPTION

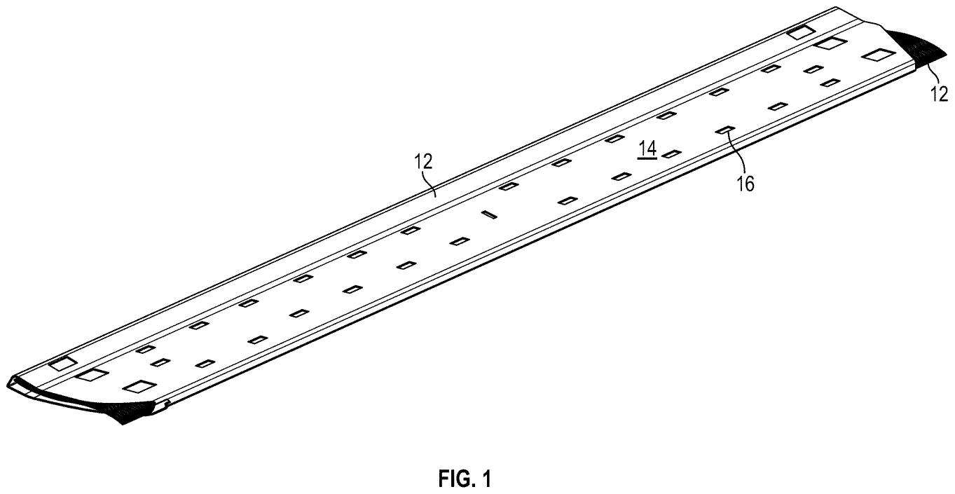

Shown in FIG. 1 is a workpiece 10 (e.g., a running board for a light duty pickup truck) having a tubular structure defining a hollow interior with open ends into which a blast shield 12 is inserted. Blast shield 12 prevents laser light used to cut apertures 16 into an upper wall 14 of workpiece 10 from impinging on an opposite wall 18. Blast shield 12 is designed to absorb, conduct and diffuse energy from the laser to prevent damage to, and allow repeated reuse of the blast shield, as well as to prevent cutting and/or marring of surfaces of wall 18.

Another advantage is that blast shield 12 captures and collects dross generated during the cutting process. This prevents the dross from being deposited onto the surface of wall 18, which can otherwise promote corrosion. It can also prevent contamination of electrolyte tanks used during subsequent electrolyte deposition of a coating, and redeposition of dross particles onto the workpiece during electrolytic coating (e.g., chrome plating) of the workpiece.

Blast shield 12 includes a metal sheet material having a thermal conductivity and a heat capacity well suited to act as a heat sink for absorption and rapid uniform distribution of the laser energy that impinges on the blast shield, while also being relatively inexpensive. Preferably, the metal sheet material has a thermal conductivity of from about 75 to 240 Wm⁻¹ K⁻¹ at 273.15° K and a heat capacity of from 400 to 950 J Kg⁻¹ K⁻¹. Preferred metal sheet materials for the blast shield include aluminum, aluminum alloys, iron and stainless steel, with aluminum being particularly preferred based on a combination of relatively high heat capacity, thermal conductivity, low cost, and high availability.

The upper surface 20 of blast shield 12 can be provided with a micro-textured topology having random or patterned surface features of a size from about 1 μm to 1000 μm. In certain embodiments, the micro-textured surface exhibits an average surface roughness (Rₐ), as determined in accordance with procedures provided in ASME B46.1-2009, of from 1 μm to 100 μm. The micro-textured surface can be relatively random as achieved using mechanical (e.g., abrasive) or chemical (e.g., etching) techniques or patterned (controlled) using laser machining techniques. The micro-textured topology of the surface 20 diffracts or scatters laser light impinging on surface 20 to reduce the amount of energy absorbed at the point of impingement and more uniformly distribute the energy along the surface. The micro-textured surfaces may be provided on one or both opposite sides of blast shield 12, along the entire surface or along selected surfaces corresponding to workpiece cutting locations.

Surface 20 can be provided with a highly reflective and highly heat conductive coating to reduce laser energy absorption at the location where the laser light beam impinges upon the surface 20, and to rapidly spread any absorbed energy along the surface and into the metal sheet substrate. Because only a relatively thin coating (e.g., 5 to 10 μm) is needed, scarce and expensive metal coatings can be employed. Preferred metal coatings are gold and silver, each of which are highly reflective and have a thermal conductivity significantly higher than aluminum. The coating can be sputtered or electrochemically deposited.

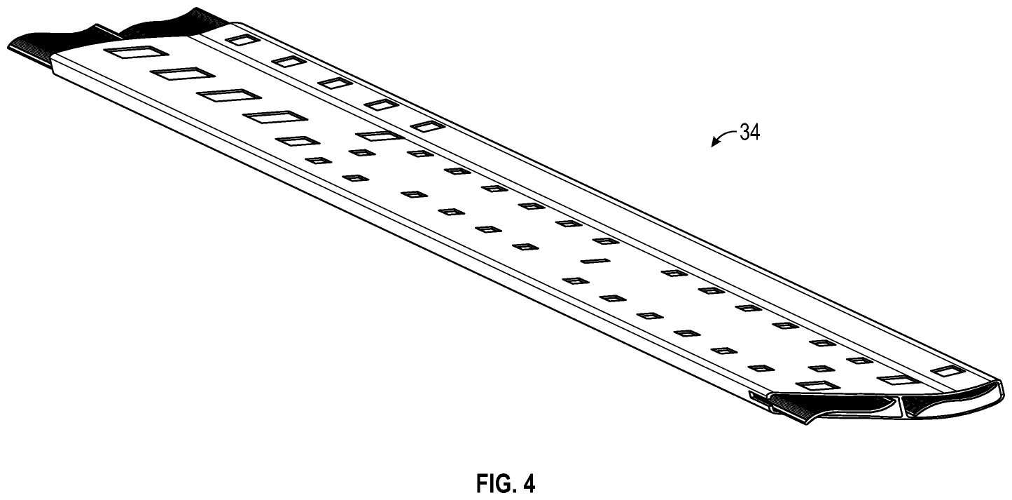

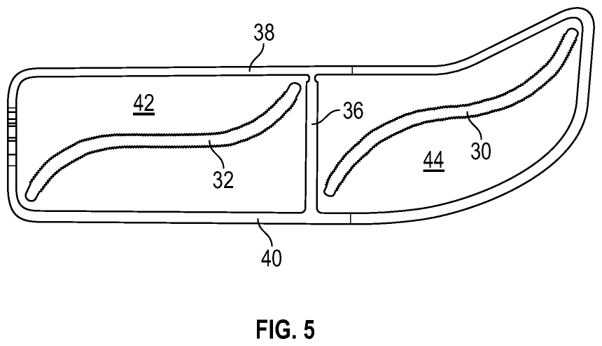

FIGS. 4 and 5 illustrate the use of two blast shields 30 and 32 in a light duty pickup truck running board 34 having a tubular profile in which the hollow interior is separated into two sections by a reinforcing web 36. This design allows production of a wider running board and/or a running board having slightly thinner upper and lower walls (38 and 40, respectively). Except for being sized and shaped to fit into separate hollow sections 42, 44, blast shields 30, 32 are otherwise similar to blast shield 12 (previously described with reference to FIGS. 1-3).

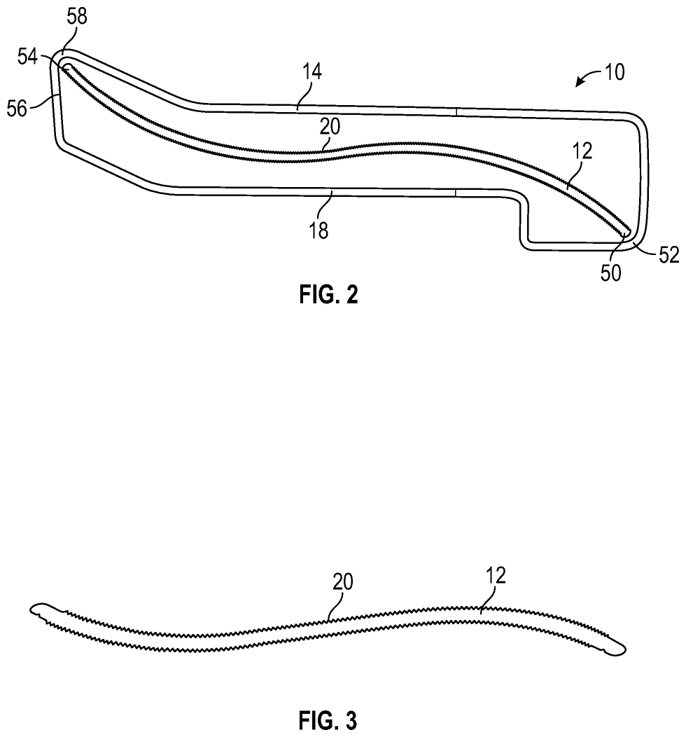

Blast shields 12, 30 and 32 are preferably curved such that they can be placed into the hollow space or spaces defined between the wall of the workpiece that is to be laser cut and an opposing wall without requiring the use of fasteners or clamps. However, plastic or vulcanized rubber bumpers can be attached to opposite edges 50, 52 of the blast shield, or positioned between the opposite edges and respective side walls 52, 56 of the workpiece to establish a frictional fit between the blast shield and the workpiece. The dross collected on the blast shield is mostly metal (e.g., aluminum) from the workpiece, which can be recycled with the blast shield after repeated use (e.g., about 50 production cycles). For example, as illustrated in FIGS. 2 (and 5 by analogy), a first edge 50 of blast shield 12 rests on a lower corner 52 of workpiece 10, while an opposite second end 54 of blast shield 12 rests against an opposite sidewall 56 or a corner 58 of workpiece 10 diagonally opposite of corner 52.

Use of the blast shields 12, 30 and 32 involves positioning of the blast shield or shields within the space or spaces defined between a first wall (e.g., 14 or 38) which is to be cut (such as to form apertures for attachment of plastic or rubber step pads), and a second wall (e.g., 18 or 40) of the workpiece opposite the first wall relative to the direction of the laser light beam of the cutting tool, such that laser light penetrating the wall to be cut impinges on the surface (e.g., 20) of the blast shield. Preferably, the laser beam is focused on the wall to be cut with the power adjusted to facilitate short cycle times without concern for damaging the opposite wall (e.g., wall 18 or 40). The blast shields can be curved or contoured to position a section of surface (e.g., 20) on which laser light beams will impinge approximately midway between the wall to be cut (e.g., 14 or 38) and the second opposite wall (e.g., 18 or 40).

While the present invention is described herein with reference to illustrated embodiments, it should be understood that the invention is not limited hereto. Those having ordinary skill in the art and access to the teachings herein will recognize additional modifications and embodiments within the scope thereof. Therefore, the present invention is limited only by the claims attached herein.

1. A laser cutting tool blast shield, comprising:
a metal sheet substrate having a micro-textured topology on a portion of its surface, the metal substrate having a thermal conductivity of 75 to 240 Wm⁻¹ K⁻¹ at 273.15° K, and a heat capacity of from 400 to 950 JKg⁻¹ at 273.15° K; and
a metal coating deposited over the micro-textured surface, the metal coating having a thermal conductivity greater than the thermal conductivity of the substrate.

2. The laser cutting tool blast shield of claim 1, wherein the metal coating is gold.

3. The laser cutting tool blast shield of claim 1, wherein the metal coating is silver.

4. The laser cutting tool blast shield of claim 1, wherein the substrate is aluminum or an aluminum alloy.

5. The laser cutting tool blast shield of claim 1, wherein the thickness of the metal sheet substrate is about 1/16 inch to about ⅝ inch.

6. The laser cutting tool blast shield of claim 1, wherein the micro-textured surface has an average surface roughness (Rₐ), as determined in accordance with ASME B46.1-2009, of from 1 μm to 100 μm.

7. A process for laser cutting a first surface of a workpiece without damaging a second opposite surface of the workpiece, comprising:
positioning a blast shield between the first surface of the workpiece and the second surface of the workpiece, the blast shield comprising a metal sheet substrate having a micro-textured topology on a portion of its surface; and
laser cutting the first surface with the laser light beam directed toward the micro-textured surface of the blast shield underlying the first surface of the workpiece.

8. The process of claim 7, wherein the metal substrate has a thermal conductivity of 75 to 240 Wm⁻¹ K⁻¹ at 273.15° K.

9. The process of claim 7, wherein the metal substrate has a heat capacity of from 400 to 950 JKg⁻¹ at 273.15° K.

10. The process of claim 7, wherein the micro-textured surface is coated with a metal having a thermal conductivity greater than the thermal conductivity of the substrate.

11. The process of claim 7, wherein the metal coating is gold.

12. The process of claim 7, wherein the metal coating is silver.

13. The process of claim 7, wherein the substrate is aluminum or an aluminum alloy.

14. The process of claim 7, wherein the thickness of the metal sheet substrate is about 1/16 inch to about ⅝ inch.

15. The process of claim 7, wherein the micro-textured surface has an average surface roughness (Rₐ), as determined in accordance with ASME B46.1-2009, of from 1 μm to 100 μm.

16. The process of claim 7, wherein the blast shield is provided with a curved contour to facilitate placement of the blast shield approximately midway between the first and second surface.
